(19) United States
(12) Patent Application Publication
(10) Pub. No.: US 2008/0268557 A1
(43) Pub. Date: Oct. 30, 2008

(54) METHOD FOR MEASURING A THIN FILM THICKNESS

(75) Inventors: Wen-Ping LIANG, Zhonghe City (TW); Kuo Hui SU, Taipei City (TW)

Correspondence Address: INGRASSIA FISHER & LORENZ, P.C., 7010 E. COCHISE ROAD, SCOTTSDALE, AZ, 85253, US

(73) Assignee: NANYA TECHNOLOGY CORP., Taoyuan (TW)

(21) Appl. No.: 11/945,384

(22) Filed: Nov. 27, 2007

(30) Foreign Application Priority Data
Apr. 24, 2007 (TW) 96114357

(51) Int. Cl. H01L 21/66

(52) U.S. Cl. 438/16; 257/E21.53

(57) ABSTRACT

A method for measuring a thin film thickness is provided. The method includes the following steps: providing a plurality of structures, each including a semiconductor substrate, a thin film, and a metal layer; measuring resistances of the metal layers of the plurality of structures and thicknesses of the thin films of the plurality of structures to obtain a plurality of resistance values and a plurality of corresponding thickness values; establishing a thickness-resistance table based on the plurality of resistance values and thickness values; providing a structure to be tested including a semiconductor substrate, a thin film, and a metal layer; and measuring resistance of the metal layer of the structure to be tested to determine a thickness value of the thin film of the structure to be tested according to the thickness-resistance table.

### CROSS REFERENCE TO RELATED APPLICATIONS

This application claims the right of priority based on Taiwan Patent Application No. 096114357 entitled “METHOD FOR MEASURING A THIN FILM THICKNESS”, filed on Apr. 24, 2007, which is incorporated herein by reference and assigned to the assignee herein.

### FIELD OF INVENTION

The invention is generally related to a method for measuring a thin film thickness, especially to a method for obtaining a thin film thickness based on a thickness-resistance table.

### BACKGROUND OF THE INVENTION

During the process of manufacturing semiconductor devices, numerous thin film structures are formed for isolation, insulation, or some other electrical considerations. The thickness of such a thin film plays critical role in the semiconductor process, which has great impact on the conductivity and insulating property of the structure. Any inadequate thickness of the thin film may cause open circuit failure or short circuit failure in the structure, and further reduce the process yield and reliability.

As the feature size of the semiconductor device shrinks, the thickness of thin film becomes thinner and thinner, and the technology for measuring thin film thickness also becomes more and more complex. In addition, for measuring thickness of extra-thin film (for example, smaller than 3 nanometers), it is difficult to incorporate the conventional measuring instrument into the existing production line. Therefore, the thin film measurement needs to be performed off the production line, which not only incurs extra cost but also increases the process time.

Therefore, it is necessary to provide a method for measuring a thin film thickness to determine thickness of thin film accurately and quickly.

### SUMMARY OF THE INVENTION

In light of the drawbacks of the prior art, the present invention provides a method for measuring thickness of an extra-thin film (e.g. smaller than 3 nanometers).

According to one aspect of the present invention, a method for measuring a thin film thickness is provided. The method includes the following steps: providing a plurality of structures, each including a semiconductor substrate, a thin film on the semiconductor substrate, and a metal layer on the thin film; measuring resistances of the metal layers of the plurality of structures and thicknesses of the thin films of the plurality of structures to obtain a plurality of resistance values and a plurality of corresponding thickness values; establishing a thickness-resistance table based on the plurality of resistance values and thickness values; providing a structure to be tested including a test semiconductor substrate, a test thin film on the test semiconductor substrate, and a test metal layer on the test thin film; and measuring resistance of the test metal layer to determine a thickness value of the test thin film according to the thickness-resistance table.

Other aspects of the present invention would be stated and easily understood through the following description or the embodiments of the present invention. The aspects of the present invention would be appreciated and implemented by the elements and their combinations pointed out in the appended claims. It should be understood that the above summary of the invention and the following detailed description are only illustrative but not to limit the present invention.

### BRIEF DESCRIPTION OF THE PICTURES

The present invention is illustrated by way of example and not intended to be limited by the figures of the accompanying drawing, in which like notations indicate similar elements.

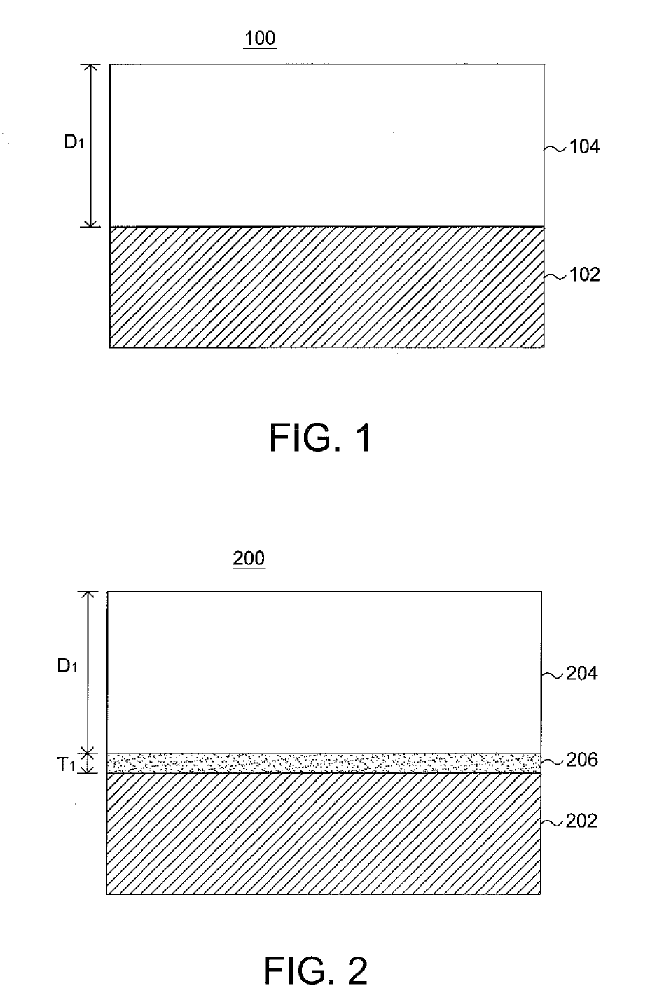

FIGS. 1-3 illustrate semiconductor structures with different thin film thicknesses in accordance with one embodiment of the present invention;

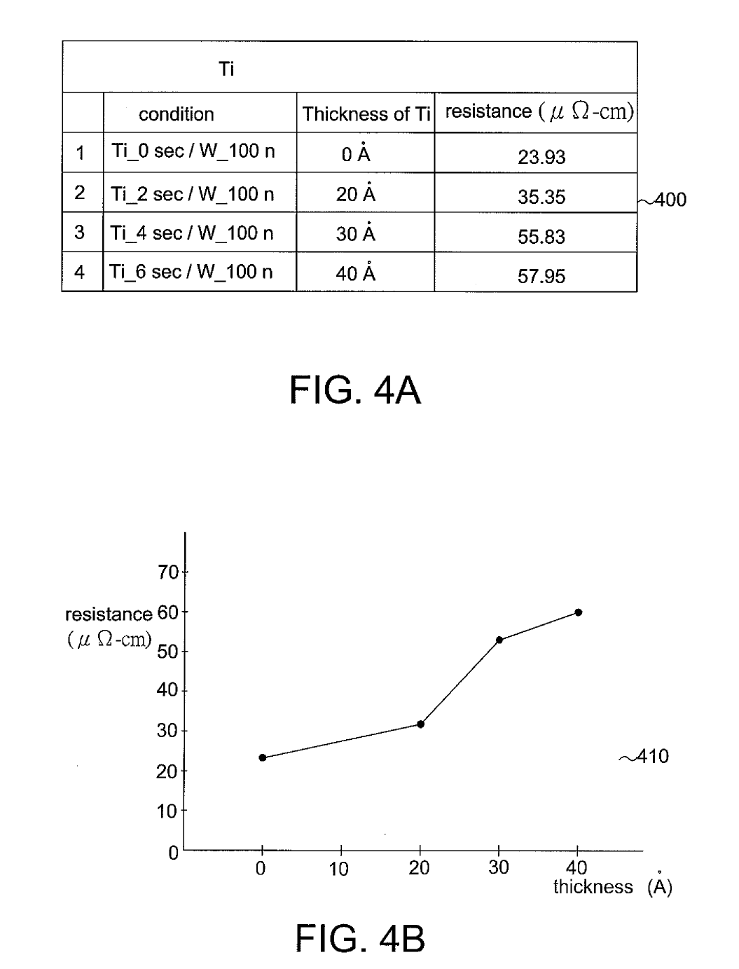

FIGS. 4A-4B illustrate a thickness-resistance table and a curve established in accordance with one embodiment of the present invention;

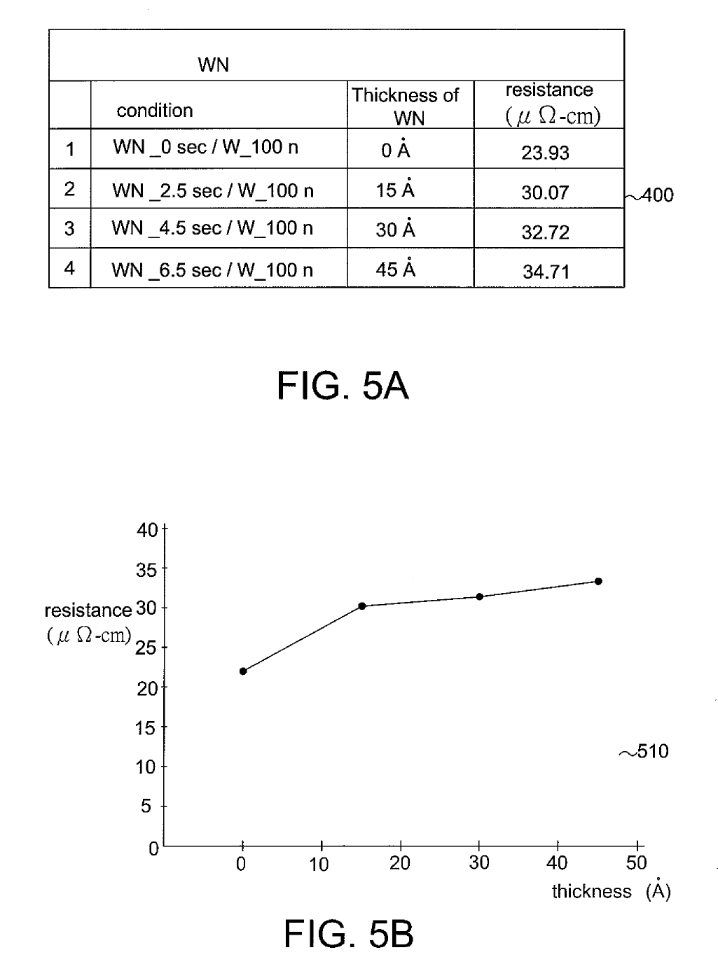

FIGS. 5A-5B illustrate a thickness-resistance table and a curve established in accordance with another embodiment of the present invention; and

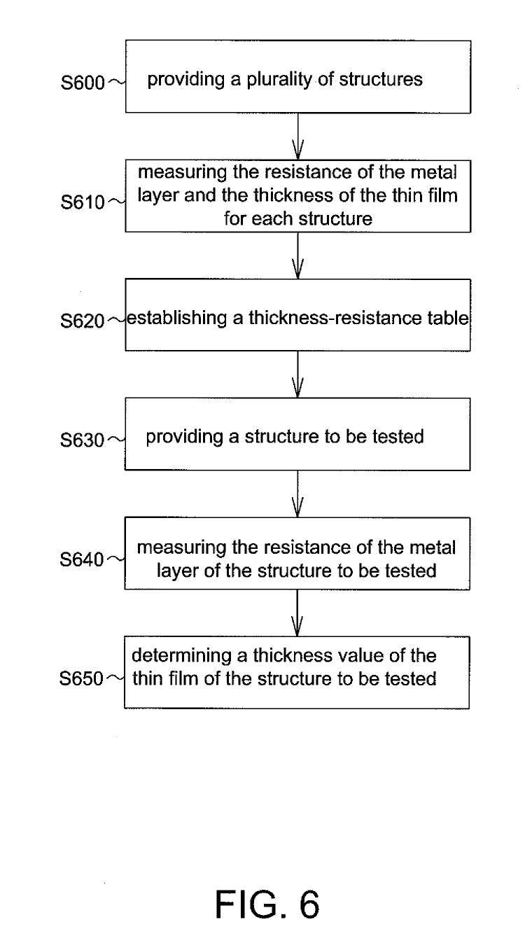

FIG. 6 is a schematic flow chart depicting a method for measuring thin film thickness in accordance with the present invention.

### DETAILED DESCRIPTION OF THE INVENTION

The present invention discloses a method for measuring a thin film thickness. The objects, embodiments, features and advantages of the present invention would be more apparent by referring to the following description of the preferred embodiments and FIGS. 1-6. However, the apparatuses, elements, and steps of the method described in the following embodiments are intended to illustrate the present invention, but not to limit the scope of the invention. It is noted that the drawings of the present application are not drawn to scale.

Each layer built on the substrate in the present invention may be formed by the methods known to one skilled in the art, such as deposition, chemical vapor deposition, or atomic layer deposition (ALD), and so on.

Referring to FIG. 1, a first structure 100 including a substrate 102 and a metal layer 104 formed on the substrate 102 is provided. The substrate 102 may be any adequate semiconductor substrate or the known silicon wafer, or any substrate which needs to be built with a thin film during the semiconductor process. The material of the metal layer 104 may be a low resistance metal, which includes, but not limited to, tungsten or aluminum. The thickness D1 of the metal layer 104 may vary with applications and is preferably about 50 nanometers to about 150 nanometers. Next, a resistance value R0 of the metal layer 104 is measured, and typically about 23.9 μΩ/cm in the case that the material of the metal layer 104 is tungsten and the substrate 102 is a silicon substrate,

According to the embodiment of the present invention, the resistance of the metal layer 104 is susceptible to material it contacts with. Therefore, if there is a thin film between the substrate 102 and the metal layer 104, the resistance of the metal layer 104 will vary with material and thickness of this thin film. The present invention utilizes this characteristic of the metal layer 140 to provide a method for obtaining a thin film thickness by measuring the resistance of the metal layer 104.

Referring to FIG. 2, a second structure 200 including a substrate 202, a thin film 206 formed on the substrate 202, and a metal layer 204 formed on the thin film 206 is provided. Typically, the materials of the substrate 202 and the metal layer 204 are the same as those of the substrate 102 and the metal layer 104 shown in FIG. 1, respectively. Next, a resistance value R1 of the metal layer 204 of the structure 200 is measured. In this embodiment, the thickness of the metal layer 204 is the same as the thickness D1 of the metal layer 104 for avoiding any possible errors. However, the thickness of the metal layer 204 almost has no influence on the resistance value R1, and therefore the thickness of the metal layer 204 is not limited in the present invention. Next, a measuring instrument, such as a Transmission Electron Microscope (TEM) or a Scanning Electron Microscope (SEM), is employed to measure the thickness of the thin film 206, and therefore a thickness value T1 corresponding to the resistance value R1 is obtained.

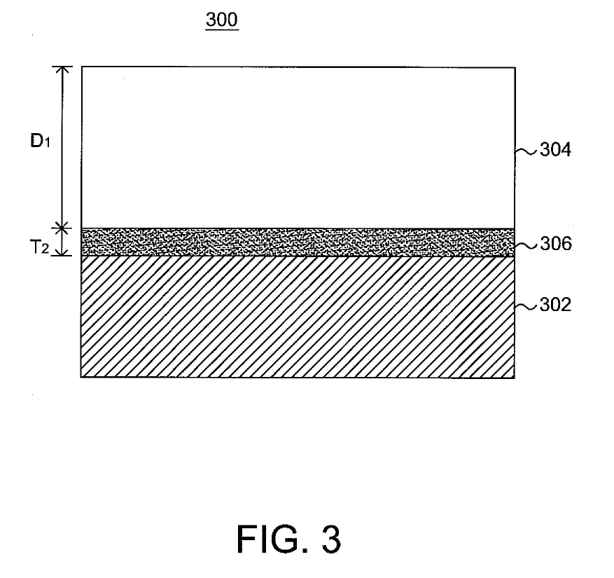

Next, referring to FIG. 3, a third structure 300 including a substrate 302, a thin film 306 formed on the substrate 302, and a metal layer 304 formed on the thin film 306 is provided. Typically, the materials of the substrate 302 and the metal layer 304 are also the same as those of the substrate 102 and the metal layer 104 shown in FIG. 1, respectively. Next, a resistance value R2 of the metal layer 304 of the structure 300 is measured, and the thickness of the thin film 306 is measured by using a measuring instrument, such as TEM or SEM to obtain a thickness value T2 corresponding to the resistance value R2. It should be noted that the thickness value T2 of the thin film 306 in FIG. 3 is preferably different from the thickness value T1 of the thin film 206 in FIG. 2, which may be achieved by controlling the fabricating times of the thin film 306 and the thin film 206. For example, when using a conventional deposition process to form the thin films 206 and 306, the deposition time of the thin film 206 may be 2 seconds, and the deposition time of the thin film 306 may be 3 seconds.

Three sets of the resistance values of metal layers with respective corresponding thickness values of the thin films can be obtained based on the structures shown in FIGS. 1-3, wherein the thickness value of the thin film corresponding to the resistance value R0 is 0. In other embodiments of the present invention, N structures, which are similar to the structure 200 or the structure 300, with thin films of different thicknesses are provided, and then the thicknesses of thin films and resistance values of corresponding metal layers are measured to obtain N sets of measuring data. Generally, the larger the number N is, the higher the precision of thickness measurement is, but the number N is not limited to any particular number in the present invention. The material of thin film 206 or 306, for example, includes, but not limited to, titanium, titanium nitride, or tungsten nitride, with thickness being smaller than about 10 nanometers, preferably being smaller than about 3 nanometers.

Referring to FIGS. 4A and 4B, a thickness-resistance table 400 and a curve 410 are established according to a plurality of the above-mentioned obtained resistance values of metal layers and corresponding thickness values of thin films. In this embodiment, four structures with thin films of different thickness values are provided, and then the resistance values of four metal layers and the thickness values of four thin films are measured. In this embodiment, the material and thickness of each metal layer are tungsten and 100 nanometers respectively, the material of each thin film is titanium, and the deposition times for forming the four thin films are 0 second, 2 seconds, 4 seconds, and 6 seconds respectively. The measured thickness values of the thin films are 0 Å, 20 Å, 30 Å, and 40 Å, respectively, and the resistance values of the metal layers are 23.93 μΩ/cm, 35.35 μΩ/cm, 55.83 μΩ/cm, and 57.95 μΩ/cm, respectively. Hence, in future, according to the established thickness-resistance table 400 and curve 410, a thickness value of a titanium thin film to be tested can be determined by measuring a resistance value of a tungsten metal layer above the titanium thin film to be tested. For example, after forming a titanium thin film and a tungsten metal layer subsequently on a silicon substrate, if the resistance of the tungsten metal layer is measured to be, for example, 41.5 μΩ/cm, then the thickness of the titanium thin film can be determined to be 23 Å according to the thickness-resistance table 400 and curve 410.

Referring to FIGS. 5A and 5B, a thickness-resistance table 500 and a curve 510 are shown in accordance with another embodiment of the present invention. In this embodiment, the material and thickness of each metal layer are tungsten and 100 nanometers, respectively, the material of each thin film is tungsten nitride, and the deposition times for forming the four thin films are 0 second, 2.5 seconds, 4.5 seconds, and 6.5 seconds respectively. The measured thickness values of the thin films are 0 Å, 15 Å, 30 Å, and 45 Å, respectively, and the corresponding resistance values of the metal layers are 23.93 μΩ/cm, 30.07 μΩ/cm, 32.72 μΩ/cm, and 34.71 μΩ/cm respectively. Hence, in future, according to the established thickness-resistance table 500 and curve 510, a thickness value of a tungsten nitride thin film to be tested can be determined by measuring a resistance value of a tungsten metal layer above the tungsten nitride thin film to be tested.

FIG. 6 is a schematic flow chart depicting a method for measuring a thin film thickness according to an embodiment of the present invention. First, in step S600, a plurality of structures are provided, each including a semiconductor substrate, a thin film on the semiconductor substrate, and a metal layer on the thin film. The material of the metal layer may be a low-resistance metal, such as tungsten or aluminum, and the material of the thin film may be titanium, titanium nitride, tungsten nitride, or other material having no chemical reaction with the metal layer. Generally, the thickness of the metal layer is about 50 nanometers to about 150 nanometers, and the thickness of the thin film is smaller than about 10 nanometers. Next, in step S610, for each structure, the resistance of the metal layer and the thickness of the thin film are measured to obtain a plurality of resistance values and a plurality of corresponding thickness values. The method for measuring the thin film thickness may be performed by using a measuring instrument, such as TEM or SEM. Next, in step S620, a thickness-resistance table is established based on the plurality of measured resistance values and corresponding thickness values. Thereafter, a thickness of a thin film formed during the manufacturing process can be obtained easily based on the thickness-resistance table. For example, as shown in step S630, when a structure to be tested including a semiconductor substrate, a thin film on the semiconductor substrate, and a metal layer on the thin film is provided, the thickness of the thin film of the structure to be tested can be obtained according to the thickness-resistance table established in step S620. First, in step S640, the resistance of the metal layer of the structure to be tested is measured. Next, in step S650, the resistance value obtained in step S640 is compared to the thickness-resistance table to determine a thickness value of the thin film of the structure to be tested.

In the present invention, the relation between the metal layer resistance and the thin film thickness is established in advance, and therefore during the subsequent process, the thickness of each thin film can be determined easily by measuring the resistance of the corresponding metal layer. The complicated measuring instrument, such as Transmission Electron Microscopy (TEM) or Scanning Electron Microscope (SEM), only needs to be used as establishing the thickness-resistance table. After the thickness-resistance table has been established, the measurement of thin film thickness can be performed on the existing production line, without any off-line measurement, and therefore the cost of the process can be reduced and the process time can also be shorten.

While this invention has been described with reference to the illustrative embodiments, these descriptions should not be construed in a limiting sense. Various modifications of the illustrative embodiment, as well as other embodiments of the invention, will be apparent upon reference to these descriptions. It is therefore contemplated that the appended claims will cover any such modifications or embodiments as falling within the true scope of the invention and its legal equivalents.

1. A method for measuring a thin film thickness, the method comprising the following steps:
providing a plurality of structures, each of the plurality of structures comprising a semiconductor substrate, a thin film on the semiconductor substrate, and a metal layer on the thin film;
measuring resistances of the metal layers of the plurality of structures and thicknesses of the thin films of the plurality of structures to obtain a plurality of resistance values and a plurality of corresponding thickness values of the thin films;
establishing a thickness-resistance table based on the plurality of resistance values of the metal layers and thickness values of the thin films;
providing a structure to be tested, the structure to be tested comprising a test semiconductor substrate, a test thin film on the test semiconductor substrate, and a test metal layer on the test thin film; and
measuring resistance of the test metal layer to determine a thickness value of the test thin film according to the thickness-resistance table.

2. The method for measuring the thin film thickness of claim 1, wherein the step of measuring thicknesses of the thin films of the plurality of structures is performed by using a Transmission Electron Microscope (TEM) or a Scanning Electron Microscope (SEM).

3. The method for measuring the thin film thickness of claim 1, wherein the step of providing the plurality of structures and the step of providing the structure to be tested comprise:
forming the metal layers and the test metal layer with a low-resistance metal.

4. The method for measuring the thin film thickness of claim 3, further comprising forming the metal layers and the test metal layer with tungsten or aluminum.

5. The method for measuring the thin film thickness of claim 1, wherein the step of providing the plurality of structures and the step of providing the structure to be tested comprise:
forming the thin films and the test thin film with titanium, titanium nitride, or tungsten nitride.

6. The method for measuring the thin film thickness of claim 1, wherein the step of providing the plurality of structures and the step of providing the structure to be tested comprise:
forming the metal layers and the test metal layer each with thickness between about 50 nanometers to about 150 nanometers.

7. The method for measuring the thin film thickness of claim 1, wherein the step of providing the plurality of structures and the step of providing the structure to be tested comprise:
forming the thin films and the test thin film each with thickness smaller than 10 nanometers.
